(19) United States
(12) Patent Application Publication
(10) Pub. No.: US 2024/0413176 A1
(43) Pub. Date: Dec. 12, 2024

(54) IMAGING DEVICE

(71) Applicant: SONY SEMICONDUCTOR SOLUTIONS CORPORATION, KANAGAWA (JP)

(72) Inventors: NAOYUKI OSAWA, KANAGAWA (JP); YOSHIMICHI KUMAGAI, KANAGAWA (JP); MASASHI BANDO, KANAGAWA (JP); TORU SHIRAKATA, KANAGAWA (JP); SHUNYA AKIYAMA, KANAGAWA (JP); TAKASHI ABE, KANAGAWA (JP)

(21) Appl. No.: 18/700,861

(22) PCT Filed: Oct. 18, 2022
(86) PCT No.: PCT/JP2022/038702

§ 371 Date: Apr. 12, 2024

(30) Foreign Application Priority Data
Oct. 25, 2021 (JP) 2021-174061

(51) Int. Cl. H01L 27/146; H04N 25/778; H04N 25/78

(52) U.S. Cl. CPC H01L 27/14603; H01L 27/1463; H01L 27/14636; H01L 27/1464; H01L 27/14645; H04N 25/778; H04N 25/78

(57) ABSTRACT

In order to solve the foregoing problem, the present disclosure provides an imaging device composed of a plurality of pixels, wherein a first pixel among the plurality of pixels includes: a first photoelectric conversion element; a first power storage unit; a first transfer element that enables a conductive state or a non-conductive state between the first photoelectric conversion element and the first power storage unit; and a first amplifying element that amplifies an image signal on the basis of a charge stored by photoelectric conversion in at least any of adjacent pixels, including a second pixel, that are adjacent to the first pixel, the second pixel including: a second amplifying element that amplifies an image signal based on a charge stored in the first power storage unit by photoelectric conversion of the first photoelectric conversion element, and a second distance between the first power storage unit and the second amplifying element is shorter than a first distance between the first power storage unit and the first amplifying element.

### TECHNICAL FIELD

The present disclosure relates to an imaging device.

### BACKGROUND ART

There has been known an imaging device such as those represented by MOS-type image sensors such as CMOS (Complementary Metal Oxide Semiconductor) that reads out a signal charge stored in an image sensor to a floating diffusion (FD) and connects the floating diffusion to an amplifier transistor to convert the signal charge into a voltage. Also, an element isolation structure has been generally used for the purpose of preventing a signal from being unreadable due to short-circuiting of the floating diffusion and the amplifier transistor.

### CITATION LIST

### Patent Literature

### [PTL 1]

JP 2008-205022A

### SUMMARY

### Technical Problem

However, an element separation region arranged in a pixel needs to have a width for separating a diffusion layer in a horizontal direction. This increases the wiring that connects the floating diffusion and the amplifier transistor, increasing the parasitic capacitance of the wiring portion in the floating diffusion.

The present disclosure therefore provides an imaging device capable of suppressing the parasitic capacitance of the wiring in the floating diffusion.

### Solution to Problem

In order to solve the above problem, according to the present disclosure, in an imaging device composed of a plurality of pixels,
a first pixel among the plurality of pixels includes:
a first photoelectric conversion element;
a first power storage unit;
a first transfer element that enables a conductive state or a non-conductive state between the first photoelectric conversion element and the first power storage unit; and
a first amplifying element that amplifies an image signal on the basis of a charge stored by photoelectric conversion in at least any of adjacent pixels, including a second pixel, that are adjacent to the first pixel,
the second pixel including:
a second amplifying element that amplifies an image signal based on a charge stored in the first power storage unit by photoelectric conversion of the first photoelectric conversion element, and
a second distance between the first power storage unit and the second amplifying element is shorter than a first distance between the first power storage unit and the first amplifying element.

The imaging device, further comprising:
a through trench arranged between the first pixel and the adjacent pixels; and
a first element separation region portion that isolates and separates the first amplifying element and the first power storage unit by an insulating substance, wherein
a width between the first amplifying element and the first power storage unit in the first element separation region portion may be greater than a width of the through trench.

The first power storage unit and the second amplifying element may be connected by a conductive portion extending across the through trench.

The imaging device, further comprising:
a semiconductor layer; and
an insulation layer,
wherein the semiconductor layer may include at least parts of the first photoelectric
conversion element, the first element separation region portion, and the through trench,
the insulation layer may include at least the conductive portion out of the conductive portion and the second amplifying element, and
the conductive portion may be any of metal wiring, a shared contact, and a polycontact.

The insulation layer may include a first insulation layer and a wiring layer, and a region of the metal wiring extending across the through trench may be arranged in the first insulation layer or the wiring layer.

The insulation layer may be arranged on a rear surface side opposite to a side where imaging light enters the first photoelectric conversion element.

The through trench may be a rear surface through trench etched from the rear surface side.

The through trench may be a front surface through trench etched from the side where the imaging light enters.

A third pixel that is different from the first pixel and the second pixel among the plurality of pixels and is adjacent to the first pixel may include:
a third photoelectric conversion element; and
a third power storage unit,
wherein
the first pixel may further include a first amplifying element that amplifies an image signal based on a charge stored in the third power storage unit by photoelectric conversion of the third photoelectric conversion element.

The first pixel may further include:
a first element separation region portion that insulates the first power storage unit and the first amplifying element, and
a width of the first element separation region portion may be greater than a width of a through trench arranged between the first pixel and the second pixel.

The first element separation region portion may have an oxide film-embedded structure.

The first element separation region portion may have an implantation separation structure obtained by ion implantation.

The plurality of pixels may have an oxide film-embedded structure and an implantation separation structure as an element separation region portion.

A connector between the metal wiring and the first power storage unit may have a contact structure.

The contact structure may be a metal structure.

The contact structure may be a polysilicon structure.

A fourth pixel that is different from the first pixel and the second pixel among the plurality of pixels and is adjacent to the first pixel may include:
a fourth photoelectric conversion element; and
a fourth power storage unit, wherein
the fourth power storage unit may be connected to the first power storage unit.

The first power storage unit may be a floating diffusion unit.

A fifth pixel that is different from the first pixel and the second pixel among the plurality of pixels and is adjacent to the second pixel may include:
a fifth amplifying element that amplifies an image signal based on a charge stored in the first power storage unit by photoelectric conversion of the first photoelectric conversion element.

The second amplifying element and the fifth amplifying element may be connected in parallel.

A fifth pixel that is different from the first pixel, the second pixel, and the fourth pixel among the plurality of pixels and is adjacent to the second pixel may include:
a reset element that has one end connected to the fourth power storage unit and the first power storage unit.

The first pixel may further include:
a second power storage unit that stores an accumulated charge obtained by the first photoelectric conversion element;
an element that has one end connected to the first power storage unit and the other end connected to the second power storage unit; and
a reset element that has one end connected to the element.

### BRIEF DESCRIPTION OF DRAWINGS

FIG. 1 is a block diagram showing a configuration example of an imaging device 1.

FIG. 2 is a circuit diagram showing an example of a circuit configuration of a pixel.

FIG. 3 is a diagram showing an example of a layout of adjacent pixels.

FIG. 4A is a cross-sectional view taken along AA of FIG. 3.

FIG. 4B is a cross-sectional view taken along AA of FIG. 3, in which the material of an element separation region portion is different from that shown in FIG. 4A.

FIG. 5 is a diagram showing a comparative example.

FIG. 6 is a circuit diagram showing an example of a circuit configuration of a pixel according to a second embodiment.

FIG. 7 is a diagram showing an example of a layout of pixels according to the second embodiment.

FIG. 8 is a diagram showing an example of another layout of pixels according to the second embodiment.

FIG. 9 is a circuit diagram showing an example of a circuit configuration of a pixel according to a third embodiment.

FIG. 10 is a diagram showing an example of a layout of pixels according to the third embodiment.

FIG. 11 is a circuit diagram showing an example of a circuit configuration of a pixel according to a fourth embodiment.

FIG. 12 is a diagram showing an example of a layout of pixels according to the fourth embodiment.

FIG. 13 is a circuit diagram showing an example of a circuit configuration of a pixel according to a fifth embodiment.

FIG. 14 is a diagram showing an example of a layout of adjacent pixels according to the fifth embodiment.

FIG. 15 is a diagram showing an example of a layout of adjacent pixels according to a sixth embodiment.

FIG. 16 is a cross-sectional view taken along AA of FIG. 15.

FIG. 17 is a diagram showing an enlargement of an Area 10 of FIG. 16.

FIG. 18 is a diagram showing an example of a layout of adjacent pixels according to a seventh embodiment.

FIG. 19 is a cross-sectional view taken along AA of FIG. 18.

FIG. 20 is a diagram showing an enlargement of an Area 20 of FIG. 19.

FIG. 21 is a diagram showing an example of a layout of adjacent pixels according to the seventh embodiment.

FIG. 22 is a cross-sectional view taken along AA of FIG. 21.

FIG. 23 is a diagram showing an enlargement of an Area 30 of FIG. 22.

FIG. 24 is a diagram showing an example of a laminated structure of the imaging device 1 according to the present embodiment.

FIG. 25 is a circuit diagram showing an example of a circuit configuration of a pixel according to a ninth embodiment.

FIG. 26 is a circuit diagram showing an example of a detailed circuit configuration of a sample-and-hold circuit.

FIG. 27 is a diagram showing an example of a layout of adjacent pixels according to the ninth embodiment.

### DESCRIPTION OF EMBODIMENTS

Hereinafter, embodiments of an imaging device will be described with reference to the drawings. Hereinafter, main components of the imaging device will be mainly described, but the imaging device may have components or functions that are not illustrated or described. The following description does not exclude components or functions that are not illustrated or described.

### First Embodiment

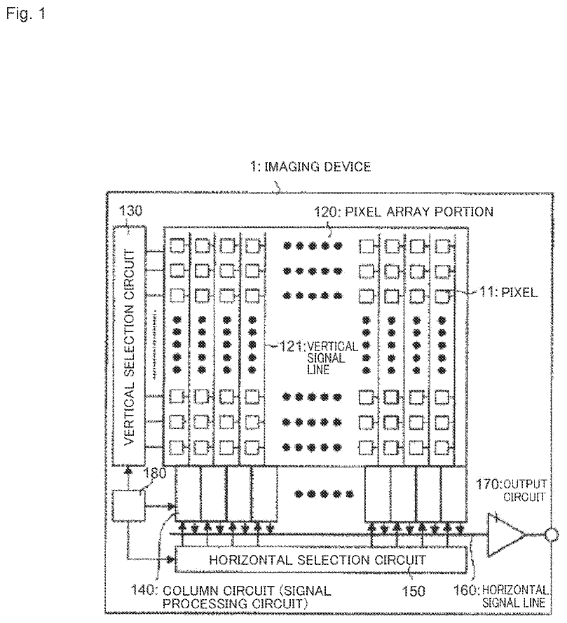

FIG. 1 is a block diagram showing a configuration example of an imaging device 1 to which the present invention is applied. As shown in FIG. 1, the imaging device 1 according to the present application example is, for example, a MOS-type image sensor. The imaging device 1 includes pixels 11 including photoelectric conversion elements, a pixel array portion 120 in which the pixels 11 are arranged two-dimensionally in a matrix, a vertical selection circuit 130, a column circuit 140 which is a signal processing circuit, a horizontal selection circuit 150, a horizontal signal line 160, an output circuit 170, a timing generator 180, and the like.

In the pixel array portion 120, a vertical signal line 121 is wired with respect to each column of pixels arranged in a matrix. A specific circuit configuration of the pixels 11 will be described later. The vertical selection circuit 130 is configured by a shift register and the like, and selectively drives each pixel 11 of the pixel array portion 120 one row at a time by sequentially outputting, row by row, a control signal for driving a transfer transistor of the pixel 11 or a control signal for driving a reset transistor. Note that the transistors according to the present embodiment may be referred to as elements.

The column circuit 140 is a signal processing circuit arranged for each horizontal pixel of the pixel array portion 120, that is, for each vertical signal line 121, and is configured by, for example, a S/H (sample-and-hold) circuit, a CDS (Correlated Doule Sampling) circuit and the like. The horizontal selection circuit 150 is configured by a shift register or the like, sequentially selects signals of the respective pixels 11 that are output from the column circuit 140, and causes the horizontal signal line 160 to output the signals. Note that FIG. 1 omits the illustration of a horizontal selection switch, for simplification of the drawing. This horizontal selection switch is sequentially on/off driven column by column by the horizontal selection circuit 150.

As a result of the selective drive by the horizontal selection circuit 150, the signals of the pixels 11 that are sequentially output column by column from the column circuit 140 are supplied to the output circuit 170 via the horizontal signal line 160, are then subjected to signal processing by this output circuit 170, such as amplification, and thereafter are output to the outside of the device. The timing generator 180 generates various timing signals and drives and controls the vertical selection circuit 130, the column circuit 140, the horizontal selection circuit 150 and the like on the basis of these various timing signals.

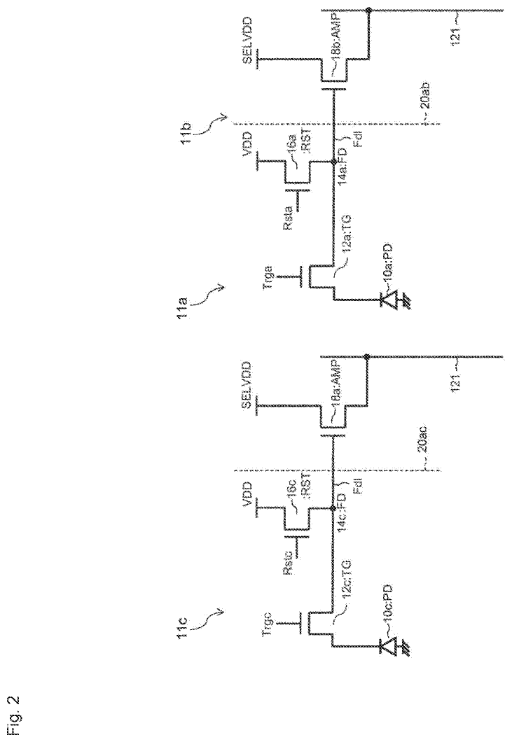

FIG. 2 is a circuit diagram showing an example of a circuit configuration of a pixel. FIG. 2 shows mainly a pixel 11a configuring the pixel array portion 120 (see FIG. 1), as well as parts of pixels 11b, 11c adjacent thereto. As shown in FIG. 2, the pixel 11a according to the present circuit example includes a photoelectric conversion element (PD) 10a, a transfer transistor (TG) 12a, an FD (floating diffusion) portion 14a, a reset transistor (RST) 16a, and an amplifying transistor 18a. The pixels 11b, 11c have the same configuration as the pixel 11a. Therefore, in the following description, b is given to the circuit configuration of the pixel 11b, c is given to the circuit configuration of the pixel 11c, the same number is given to the circuit configuration same as that of the pixel 11a, and the description of the circuit configurations of the pixel 11b and the pixel 11c may be omitted. In the present embodiment, a circuit example having the reset transistor (RST) 16a will be described, but the present embodiment is not limited thereto. As these transistors in the pixels, nMOS transistors, for example, are used.

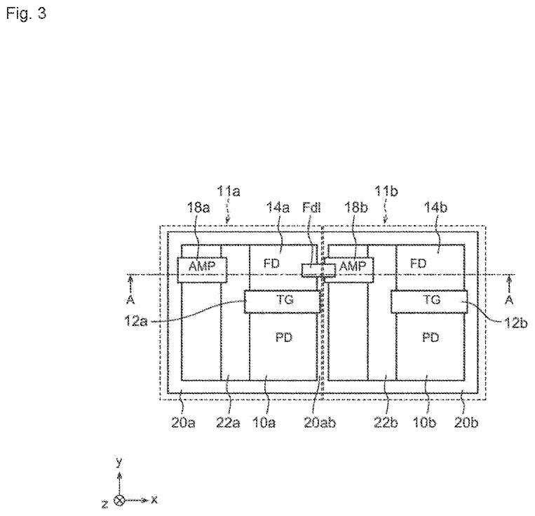

Furthermore, as will be described later using FIG. 3, in the present embodiment, the pixels 11a, 11b, 11c are surrounded by through trenches. In FIG. 2, the through trench (Full Trench Isolation: FTI) arranged between the pixel 11a and the pixel 11c is indicated with 20ac, and the through trench (Full Trench Isolation: FTI) arranged between the pixel 11a and the pixel 11b is indicated with 20ab.

The photoelectric conversion element 10a generates a charge according to the amount of light irradiated, and holds the generated charge. The photoelectric conversion element 10a is, for example, a photodiode. The transfer transistor 12a, the reset transistor 16a, and the amplifying transistor 18a are, for example, N-channel MOS transistors.

More specifically, the source of the transfer transistor 12a is connected to the cathode of the photoelectric conversion element 10a, and drain is connected to the FD portion 14a. The anode of the photoelectric conversion element 10a is connected to the ground. Further, the FD portion 14a is connected to the gate of an amplifying transistor 18b of the adjacent pixel 11b. In addition, one end of the reset transistor 16a is connected to the FD portion 14a, and the other end of the reset transistor 16a is connected to a power supply VDD.

Also, a signal line Trga is connected to the gate of the transfer transistor 12a, and a control signal is supplied to said gate. When the control signal is at a high level, the transfer transistor 12a enters a conductive state, and when the control signal is at a low level, the transfer transistor 12a enters a non-conductive state.

A signal line Rsta is connected to the gate of the reset transistor 16a, and a control signal is supplied to said gate. When the control signal is at a high level, the reset transistor 16a enters a conductive state, and when the control signal is at a low level, the reset transistor 16a enters a non-conductive state.

The transfer transistor 12a transfers a charge generated by the photoelectric conversion element 10a to the FD portion 14a. That is, this transfer transistor 12a transfers a charge by making conduction between the photoelectric conversion element 10a and the FD portion 14a. The reset transistor 16a discharges the charge stored in the FD portion 14a when in a conductive state.

The amplifying transistor 18b of the pixel 11b has a source follower configuration in which the drain thereof is connected to a selective power supply SELVDD and the source to the vertical signal line 121, wherein the amplifying transistor 18b enters an operation state when the selective power supply SELVDD is at a VDD level, to select the pixel 11a. Therefore, the potential of the FD portion 14a which has been reset by the reset transistor 16a is output to the vertical signal line 121 as a reset level. Further, the potential of the FD portion 14a after the transfer of a signal charge by the transfer transistor 12a is output to the vertical signal line 121 as a signal level (image signal). Note that the drain of the amplifying transistor 18b and the drain of the reset transistor 16a may be connected in such a manner that a power supply VDD is shared. In this case, row selection may be performed by arranging a selective transistor (SELtrg), not shown, to the source of the amplifying transistor 18b.

In this manner, the FD portion 14a of the pixel 11a is connected to the amplifying transistor 18b of the adjacent pixel 11b. Thus, the charge stored in the photoelectric conversion element 10a of the pixel 11a by photoelectric conversion is read from the adjacent pixel 11b to the vertical signal line 121 as an image signal.

Similarly, the source of a transfer transistor 12c of the pixel 11c is connected to the cathode of a photoelectric conversion element 10c and the drain thereof is connected to an FD portion 14c. The anode of the photoelectric conversion element 10c is connected to the ground. Further, the FD portion 14c is connected to the gate of the amplifying transistor 18a of the adjacent pixel 11a. In addition, one end of a reset transistor 16c is connected to the FD portion 14c, and the other end of the reset transistor 16c is connected to the power supply VDD.

Also, a signal line Trgc is connected to the gate of the transfer transistor 12c, and a control signal is supplied to said gate. When the control signal is at a high level, the transfer transistor 12c enters a conductive state, and when the control signal is at a low level, the transfer transistor 12c enters a non-conductive state.

In addition, a signal line Rstc is connected to the gate of the reset transistor 16c, and a control signal is supplied to said gate. When the control signal is at a high level, the reset transistor 16c enters a conductive state, and when the control signal is at a low level, the reset transistor 16c enters a non-conductive state.

The transfer transistor 12c transfers a charge generated by the photoelectric conversion element 10c to the FD portion 14c. That is, this transfer transistor 12c transfers a charge by making conduction between the photoelectric conversion element 10c and the FD portion 14c. The reset transistor 16a discharges the charge stored in the FD portion 14c when in a conductive state.

The amplifying transistor 18a of the pixel 11a has a source follower configuration in which the drain thereof is connected to a selective power supply SELVDD and the source to the vertical signal line 121, wherein the amplifying transistor 18a enters an operation state when the selective power supply SELVDD is at a VDD level, to select the pixel 11c. Therefore, the potential of the FD portion 14c which has been reset by the reset transistor 16c is output to the vertical signal line 121 as a reset level. Further, the potential of the FD portion 14c after the transfer of a signal charge by the transfer transistor 12c is output to the vertical signal line 121 as a signal level (image signal).

In this manner, the FD portion 14c of the pixel 11c is connected to the amplifying transistor 18a of the adjacent pixel 11a. Thus, the charge stored in the photoelectric conversion element 10c of the pixel 11c by photoelectric conversion is read from the adjacent pixel 11a to the vertical signal line 121 as an image signal.

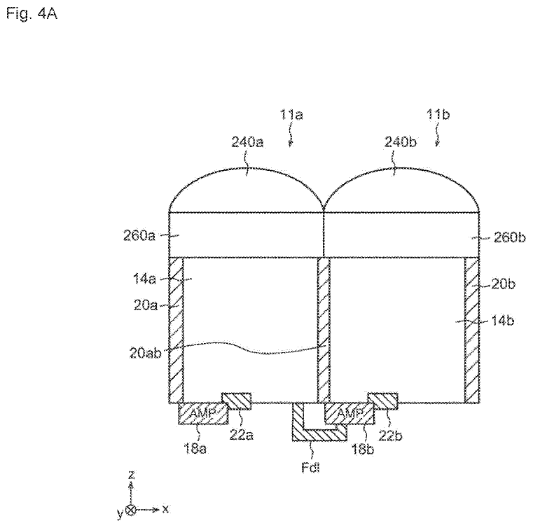

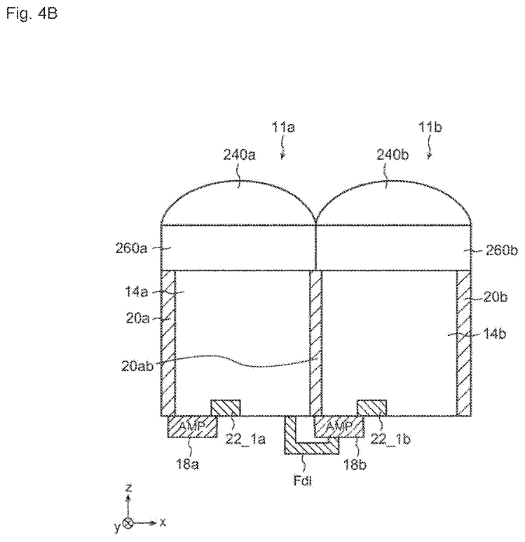

Here, examples of the pixel 11a and the pixel 11b are shown in the present embodiment using FIG. 3 and FIGS. 4A, 4B. FIG. 3 is a diagram showing an example of a layout of the adjacent pixels 11a, 11b according to the present embodiment. That is, FIG. 3 is a diagram in which the pixel array portion 120 (see FIG. 1) is viewed from the rear surface opposite to the light-receiving surface. As shown in FIG. 3, the pixel 11a is composed of the photoelectric conversion element (PD) 10a, the FD portion 14a functioning as a floating diffusion (FD), the transfer transistor 12a, the reset transistor 16a, and the amplifying transistor 18a. The other pixels have the same configuration. In this manner, a plurality of pixels are arranged in a matrix in the pixel array portion 120. For example, the adjacent pixels 11a, 11b and the like arranged in lines are in translation symmetry. In other words, when the pixel 11a is moved horizontally in an X direction, the pixel 11a overlaps with the pixel 11b, and the pixel 11b overlaps with an adjacent pixel. Note that the reset transistor 16a is stacked on a circuit substrate layer having the transfer transistor 12a and the amplifying transistor 18a, and is not shown in the present embodiment. Note that the reset transistor 16a may be arranged in the same layer as the transfer transistor 12a and the amplifying transistor 18a.

The pixel 11a is surrounded by the through trench 20a and a through trench 20ab which is the boundary between the pixel 11a and the pixel 11b, and is insulated from the adjacent pixel. Similarly, the pixel 11b is surrounded by a through trench 20b and the through trench 20ab which is the boundary between the pixel 11b and the pixel 11a, and is insulated from the adjacent pixel.

The through trenches 20a, 20b, 20ab may be rear surface through trenches (RFTI: Reverse Full Trench Isolation) or front surface through trenches (FFTI: Front Full Trench Isolation). The through trenches 20a, 20b, 20ab include, for example, an oxide film and insulate the pixels from each other. The rear surface through trenches (RFTI) are formed by etching grooves of the through trenches 20a, 20b, 20ab from the rear surface. On the other hand, the front surface through trenches (FFTI) are formed by etching the grooves of the through trenches 20a, 20b, 20ab from the front surface opposite to the rear surface.

The FD portion 14a of the pixel 11a and the amplifying transistor 18b of the pixel 11b are connected by a conductive portion Fdl extending across the through trench 20ab. The conductive portion Fdl is wiring composed of a conductor and is, for example, metal wiring. Furthermore, the amplifying transistor 18a and the FD portion 14a of the pixel 11a are separated by an element separation region portion 22a.

FIG. 4A is a cross-sectional view taken along line AA of FIG. 3. As shown in FIG. 4, one circular on-chip lens 240a, 240b is disposed in each of the pixels 11a, 11b. For example, a flattening layer, a ground insulation layer, a color filter layer or the like is configured in a layer 260a, 260b. The conductive portion Fdl is disposed on the rear surface side of the through trench 20ab and is connected so as to extend across the FD portion 14a, the amplifying transistor 18b of the pixel 11b, and the through trench 20ab. The element separation region portions 22a, 22b are shallow trench element separation regions where, for example, an insulation film such as a silicon oxide film is embedded.

FIG. 4B is a cross-sectional view taken along AA of FIG. 3 in which the material of the element separation region portions 22a, 22b is different from that shown in FIG. 4A. As shown in FIG. 4B, the element separation region portions 22a, 22b (see FIG. 3A) may be configured by element separation region portions 22_1a, 221b by, for example, implantation separation by P-type ion implantation. Thus, the element separation region portion 22a may have an oxide film-embedded structure or obtained by, for example, implantation separation by P-type ion implantation. Alternatively, a combination of both may be possible. The width of the element separation region portion 22a (see FIG. 3A) needs to be configured to be generally greater than the width of the through trench 20ab in order to maintain equal insulation properties.

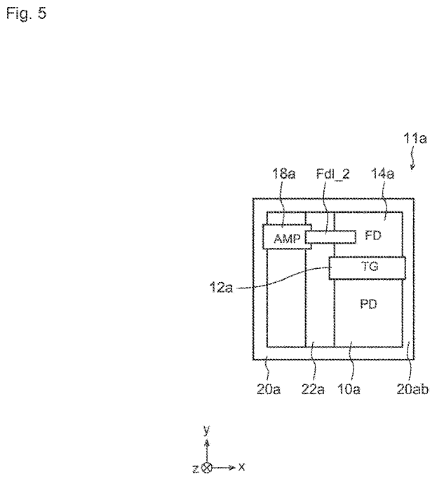

FIG. 5 is a diagram showing a comparative example. FIG. 5 shows an example in which the FD portion 14a of the pixel 11a shown in FIG. 3 and the amplifying transistor 18a are connected. A length Fdl_2L of a conductive portion Fdl_2 connecting the FD portion 14a and the amplifying transistor 18a is in the following relationship with a length FdlL of the conductive portion Fdl because the conductive portion Fdl_2 extends across the element separation region portion 22a. That is, the relationship is as follows: Fdl_2L>FdlL. Therefore, the parasitic capacitance of the conductive portion Fdl_2 is greater than the parasitic capacitance of the conductive portion Fdl.

$$\begin{matrix}[ Math . 1 ] & \\ η = \frac{q}{{C}_{FD}} G [ μ V / e ] & ( 1 )\end{matrix}$$

Equation (1) shows a conversion efficiency η of the imaging device 1 which is a CMOS image sensor. q represents a charge of an electron, G represents a gain of a source follower circuit, and C_{FD} represents a capacitance of the FD portion 14a. The capacitance C_{FD} of the FD portion 14a is a sum of a junction capacitance of an FD diffusion layer, a gate capacitance of the amplifying transistor 18b, and the parasitic capacitances of the Fd, Fdl_2. Since the conversion efficiency η is proportional to a reciprocal number of the FD capacity, an increase in the FD capacitance C_{FD} leads to a decrease in the conversion efficiency. Further, even if the length of the conductive portion Fdl_2 is the same as the length of the conductive portion Fdl, as to the parasitic capacitance of the FD wiring, the parasitic capacitance of the conductive portion Fdl becomes smaller than the parasitic capacitance of the conductive portion Fdl_2 due to the difference in material between the element separation region portion 22a and the through trench 20ab. Thus, due to the difference in material, the parasitic capacitance of the conductive portion Fdl becomes smaller than the parasitic capacitance of the conductive portion Fdl_2, and the conversion efficiency η of the CMOS image sensor becomes higher when the FD portion 14a of the pixel 11a is connected to the amplifying transistor 18b of the adjacent pixel 11b. Note that configuring the element separation region portion 22a by the through trench blocks the light that enters the photoelectric conversion element (PD) 10a via the on-chip lens 24a, lowering the light sensitivity of the CMOS image sensor.

As described above, the FD portion 14a of the pixel 11a and the amplifying transistor 18b of the adjacent pixel 11b are connected. Therefore, the parasitic capacitance of the conductive portion Fdl between the FD portion 14a of the pixel 11a and the amplifying transistor 18b of the adjacent pixel 11b can be made smaller than the parasitic capacitance obtained when connecting the FD portion 14a and the amplifying transistor 18a of the pixel 11a. As a result, the conversion efficiency η of the imaging device 1 can be further increased.

### Second Embodiment

An imaging device 1 according to a second embodiment is different from the imaging device 1 according to the first embodiment in that FD portions of a plurality of pixels share an amplifying transistor of an adjacent pixel. The differences with the imaging device 1 according to the first embodiment will be described below.

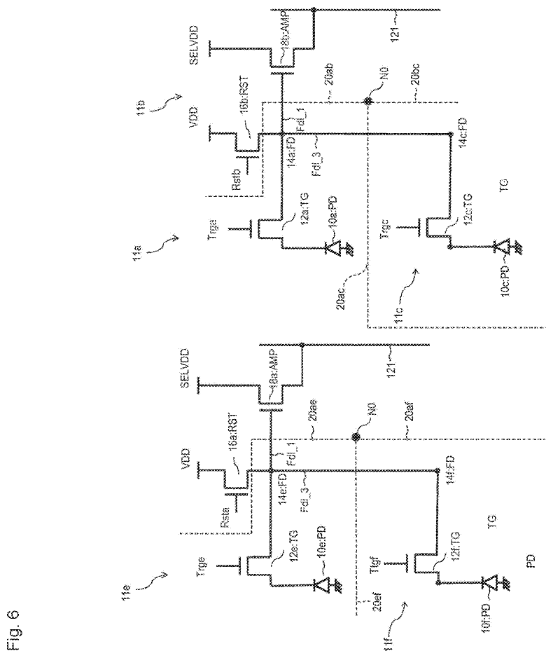

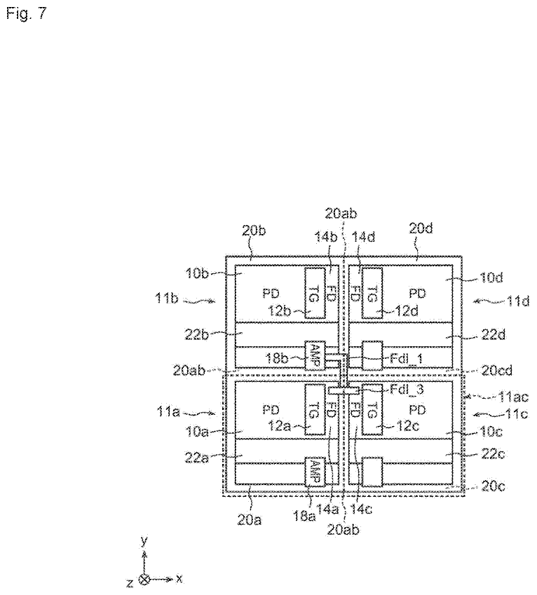

FIG. 6 is a circuit diagram showing an example of a circuit configuration of a pixel according to the second embodiment. FIG. 6 shows mainly a pixel 11a, as well as parts of pixels 11b, 11c, 11e, 11f adjacent thereto. As shown in FIG. 7, the pixel 11a according to the present circuit example includes a photoelectric conversion element (PD) 10a, a transfer transistor (TG) 12a, an FD (floating diffusion) portion 14a, a reset transistor (RST) 16a, and an amplifying transistor 18a. In the following description, the same numbers are given to the circuit configurations same as the circuit configuration of the pixel 11a, so b is given to the circuit configuration of the pixel 11b, c is given to the circuit configuration of the pixel 11c, e is given to the circuit configuration of the pixel 11e, f is given to the circuit configuration of the pixel 11f, and the description of the circuit configurations of the pixels 11b, 11c, 11e, 11f may be omitted.

In FIG. 6, the through trench arranged between the pixel 11a and the pixel 11c is indicated with 20ac, and the through trench arranged between the pixel 11a and the pixel 11b is indicated with 20ab. Similarly, the through trench arranged between the pixel 11a and the pixel 11e is indicated with 20ae, and the through trench arranged between the pixel 11a and the pixel 11f is indicated with 20af. Similarly, the through trench arranged between the pixel 11e and the pixel 11f is indicated with 20ef, and the through trench arranged between the pixel 11b and the pixel 11c is indicated with 20bc. The junctions of the through trenches are indicated with M0.

As shown in FIG. 6, the FD portion 14a of the pixel 11a and the FD portion 14c of the pixel 11c are connected to the gate of the amplifying transistor 18b of the pixel 11b. In addition, one end of the reset transistor 16b is connected to the FD portion 14a and the FD portion 14c, and the other end of the reset transistor 16b is connected to a power supply VDD.

The transfer transistor 12a transfers a charge generated by the photoelectric conversion element 10a to the FD portion 14a. Similarly, the transfer transistor 12c transfers a charge generated by the photoelectric conversion element 10c to the FD portion 14c. That is, this transfer transistor 12c transfers a charge by making conduction between the photoelectric conversion element 10c and the FD portion 14c. The reset transistor 16b discharges the charges stored in the FD portion 14a and the FD portion 14c when in a conductive state.

The amplifying transistor 18b of the pixel 11b has a source follower configuration in which the drain thereof is connected to a selective power supply SELVDD and the source to the vertical signal line 121, wherein the amplifying transistor 18b enters an operation state when the selective power supply SELVDD is at a VDD level, to select the pixels 11a, 11c. Therefore, the potentials of the FD portion 14a and the FD portion 14c which have been reset by the reset transistor 16b are output to the vertical signal line 121 as reset levels. Further, the potentials of the FD portion 14a and the FD portion 14c after the transfer of a signal charge by the transfer transistor 112 are output to the vertical signal line 121 as signal levels (image signals). Thus, the FD portion 14a and the FD portion 14c according to the present embodiment are connected in parallel.

As can be understood from above, when the transfer by the transfer transistor 12a and the transfer by the transfer transistor 12c are performed simultaneously, the charge generated by the photoelectric conversion element 10a and the charge generated by the photoelectric conversion element 10c are added up by the FD portion 14a and the FD portion 14c, which is then read from the adjacent pixel 11b to the vertical signal line 121 as an image signal. On the other hand, by performing the transfer by the transfer transistor 12a and the transfer by the transfer transistor 12c one at a time, the charge generated by the photoelectric conversion element 10a and the charge generated by the photoelectric conversion element 10c can be read from the adjacent pixel 11b to the vertical signal line 121 as image signals, respectively, in a chronological order.

Thus, the FD portion 14a of the pixel 11a and the FD portion 14c of the pixel 11c are connected to the amplifying transistor 18b of the adjacent pixel 11b. Accordingly, the charge generated by the photoelectric conversion element 10a and the charge generated by the photoelectric conversion element 10c are each read from the adjacent pixel 11a to the vertical signal line 121 as an image signal. Moreover, since the plurality of pixels 11a and 11c share the amplifying transistor 18b, the number of amplifying transistors 18b can be reduced, thereby reducing the size of the imaging device 1.

Similarly, a transfer transistor 12e transfers a charge generated by the photoelectric conversion element 10e to an FD portion 14e. Similarly, a transfer transistor 12f transfers a charge generated by a photoelectric conversion element 10f to an FD portion 14f. The reset transistor 16a discharges the charges stored in the FD portion 14e and the FD portion 14f when in a conductive state.

Similarly, the amplifying transistor 18a of the pixel 11a has a source follower configuration in which the drain thereof is connected to a selective power supply SELVDD and the source to the vertical signal line 121, wherein the amplifying transistor 18a enters an operation state when the selective power supply SELVDD is at a VDD level, to select the pixels 11e, 11f. Therefore, the potentials of the FD portion 14e and the FD portion 14f which have been reset by the reset transistor 16a are output to the vertical signal line 121 as reset levels. Further, the potentials of the FD portion 14e and the FD portion 14f after the transfer of a signal charge by the transfer transistors 12e and 12f are output to the vertical signal line 121 as signal levels.

Thus, the FD portion 14e of the pixel 11e and the FD portion 14f of the pixel 11f are connected to the amplifying transistor 18a of the adjacent pixel 11a. Accordingly, the charge generated by the photoelectric conversion element 10e and the charge generated by the photoelectric conversion element 10f are each read from the adjacent pixel 11a to the vertical signal line 121 as an image signal.

FIG. 7 is a diagram showing an example of a layout of the pixels 11a to 11d according to the second embodiment. FIG. 7 is a diagram in which the pixel array portion 120 (see FIG. 1) is viewed from the rear surface opposite to the light-receiving surface. As shown in FIG. 7, the pixels 11a to 11d are four adjacent pixels. The pixel 11a is composed of a photoelectric conversion element (PD) 10a, an FD portion 14a which is a floating diffusion (FD), and three pixel transistors, that is, a transfer transistor 12a, reset transistor 16a, and an amplifying transistor 18a. The pixel 11b has the same configuration as the pixel 11a. The pixel 11c includes the photoelectric conversion element (PD) 10a, an FD portion 14c which is a floating diffusion (FD), and a transfer transistor 12c. In other words, the pixel 11c can be configured to not include a reset transistor and an amplifying transistor. The pixel 11d has the same configuration as the pixel 11c. A plurality of such four pixels adjacent to one another within a square region are arranged in a matrix in the pixel array portion 120. The FD portion 14a of the pixel 11a and the FD portion 14c of the pixel 11c share an amplifying transistor 18b to configure a shared pixel 11ac. As with above, the reset transistors 16a, 16b (see FIG. 6) are stacked on, for example, a circuit substrate layer having the transfer transistor 12a and the amplifying transistor 18a, and are not shown in the present embodiment. The reset transistors 16a, 16b (see FIG. 6) may be arranged in the same layer as the transfer transistor 12a and the amplifying transistor 18a.

The pixels 11a to 11d are each surrounded by the through trenches 20a to 20d and the through trenches 20ab, ac, cd between pixels and insulated from an adjacent pixel. Further, the FD portion 14a of the pixel 11a and the amplifying transistor 18b of the pixel 11b are connected by the conductive portion Fdl_1 so as to extend across the through trenches 20ab, cd. Furthermore, the FD portion 14a of the pixel 11a and the FD portion 14c of the pixel 11c are connected by a conductive portion Fdl_3 extending across the through trench 20ac, via a contact structure for making an electrical contact. For example, the conductive portion Fdl_3 is wiring having a metal contact structure.

The amplifying transistor 18a and the FD portion 14a of the pixel 11a are separated by the element separation region portion 22a. Similarly, the amplifying transistor 18b and the FD portion 14b of the pixel 11b are separated by the element separation region portion 22b. The pixels 11c, d similarly have element separation region portions 22c, d. The element separation region portions 22a to 22d are shallow trench element separation regions where, for example, an insulation film such as a silicon oxide film is embedded. The element separation region portions 22a to 22d may have an oxide film-embedded structure or, for example, implantation separation obtained by P-type ion implantation. Alternatively, a combination of both may be possible. The width of the element separation region portions 22a to 22d needs to be configured to be generally greater than the width of the through trenches 20ab, cd in order to maintain equal insulation properties.

As with the comparative example described above (see FIG. 5), the length of the wiring when connecting the FD portion 14a of the pixel 11a to the amplifying transistor 18a is greater than the length of the conductive portion Fdl_1. Thus, the parasitic capacitance of the wiring when connecting the FD portion 14a of the pixel 11a to the amplifying transistor 18a becomes greater than the parasitic capacitance of the conductive portion Fdl_1. As can be understood from above, the conversion efficiency η of the CMOS image sensor becomes higher when connecting the FD portion 14a of the pixel 11a and the amplifying transistor 18b of the adjacent pixel 11b than when connecting the FD portion 14a and the amplifying transistor 18a of the pixel 11a.

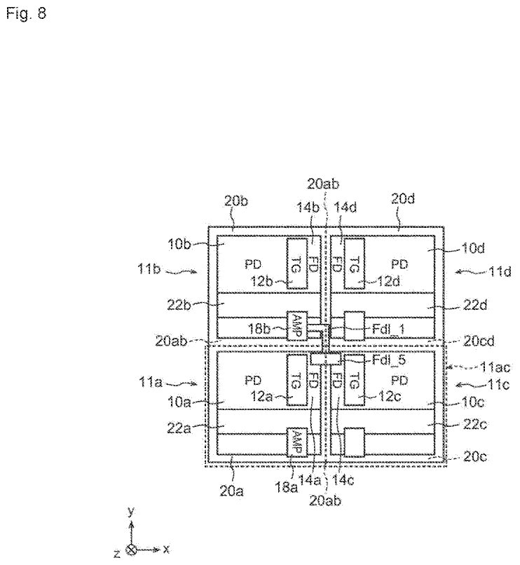

FIG. 8 is a diagram showing an example of another layout of the pixels 11a to 11d according to the second embodiment. FIG. 8 is a diagram in which the pixel array portion 120 (see FIG. 1) is viewed from the rear surface opposite to the light-receiving surface. In FIG. 8, the FD portion 14a of the pixel 11a and the FD portion 14c of the pixel 11c are connected by a conductive portion Fdl_5 via a contact structure for making an electrical contact. For example, the conductive portion Fdl_5 is wiring having a polysilicon (Poly Si) contact structure. Thus, the contact structure may be a polysilicon contact structure.

As described above, in the imaging device 1 according to the present embodiment, the FD portions 14a, 14c of the plurality of pixels 11a, 11c share the amplifying transistor 18b of the adjacent pixel 11b. Therefore, the parasitic capacitance of the wiring can be reduced more and the conversion efficiency η of the imaging device 1 which is a CMOS image sensor in a shared pixel can be made higher when connecting the FD portion 14a of the pixel 11a and the amplifying transistor 18b of the adjacent pixel 11b than when connecting the FD portion 14a and the amplifying transistor 18a of the pixel 11a.

### Third Embodiment

An imaging device 1 according to a third embodiment is different from the imaging device 1 according to the second embodiment in that FD portions of a plurality of pixels, an amplifying transistor of an adjacent pixel shared by these FD portions, and a reset transistor are arranged in the vicinity of an adjacent point of four pixels adjacent to one another. The differences with the imaging device 1 according to the second embodiment will be described below.

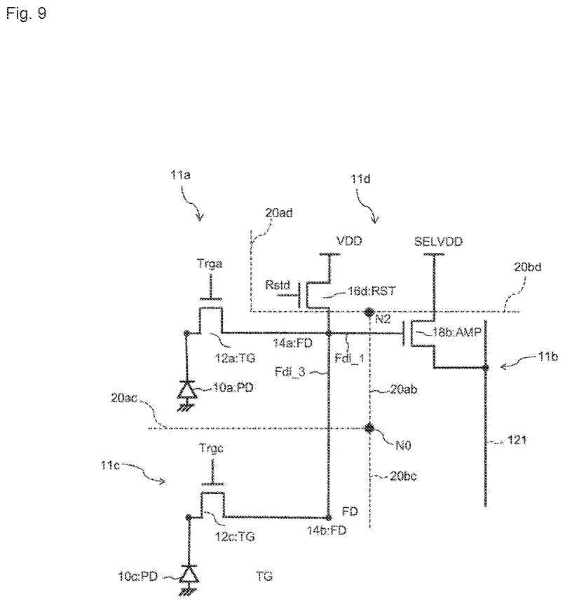

FIG. 9 is a circuit diagram showing an example of a circuit configuration of a pixel according to the third embodiment. FIG. 9 shows parts of four pixels 11a, 11b, 11c, 11d adjacent to one another. In addition, the through trenches arranged between the pixels are indicated with 20ab, ac, bc, bd, and the junctions of the through trenches are indicated with N0, N2.

As shown in FIG. 9, the FD portion 14a of the pixel 11a and the FD portion 14c of the pixel 11c are connected to the gate of the amplifying transistor 18b of the pixel 11b. Furthermore, one end of a reset transistor 16d of the pixel 11d is connected to the FD portion 14a and the FD portion 14c, and the other end of the reset transistor 16d is connected to a power supply VDD.

The amplifying transistor 18b outputs the potentials of the FD portion 14a and the FD portion 14c which have been reset by the reset transistor 16d to the vertical signal line 121 as reset levels. Further, the potentials of the FD portion 14a and the FD portion 14c obtained after a transfer of a signal charge by the transfer transistors 12a and 12c are output to the vertical signal line 121 as signal levels.

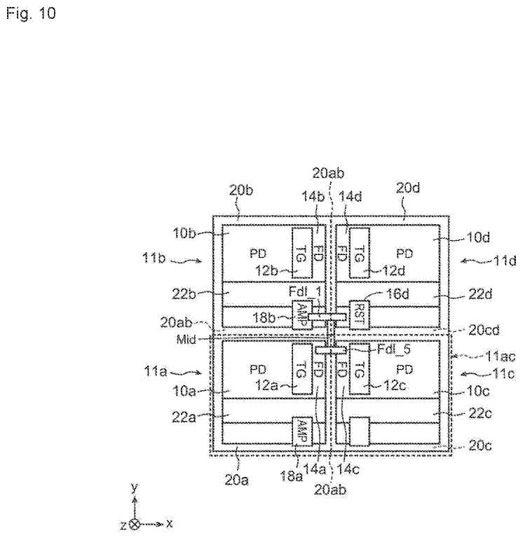

FIG. 10 is a diagram showing an example of a layout of the pixels 11a to 11d according to the third embodiment. FIG. 10 is a diagram in which the pixel array portion 120 (see FIG. 1) is viewed from the rear surface opposite to the light-receiving surface. As shown in FIG. 10, the imaging device 1 according to the third embodiment is different from the imaging device 1 according to the second embodiment in that the reset transistor 16d of the pixel 11d is arranged in the same layer as the transfer transistors (TG) 12a, 12c. Thus, by connecting the FD portion 14a and the FD portion 14c to one end of the reset transistor 16d of the pixel 11d, the reset transistor 16d, the transfer transistors (TG) 12a, 12c, and the amplifying transistor 18b can be arranged in the vicinity of an adjacent point Mid of the four pixels 11a, 11b, 11c, 11d adjacent to one another. Thus, the wiring connecting the amplifying transistor 18b and the reset transistor 16d can be made shorter, and in addition to the effects of the imaging device 1 according to the second embodiment, the parasitic capacitance of the wiring between the amplifying transistor 18b and the reset transistor 16d can be further reduced.

### Fourth Embodiment

An imaging device 1 according to a fourth embodiment is different from the imaging device 1 according to the second embodiment in that amplifying transistors of a plurality of pixels are shared by FD portions of a plurality of pixels. The differences with the imaging device 1 according to the second embodiment will be described below.

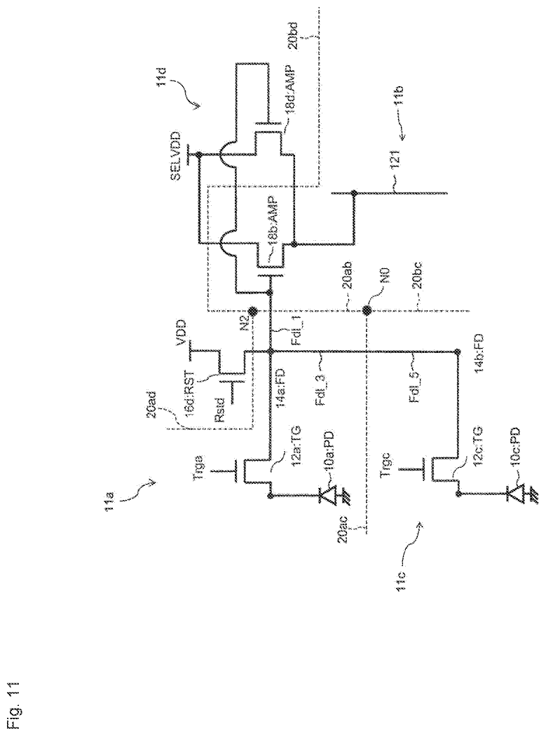

FIG. 11 is a circuit diagram showing an example of a circuit configuration of a pixel according to the fourth embodiment. FIG. 11 shows parts of four pixels 11a, 11b, 11c, 11d adjacent to one another. In addition, the through trenches arranged between the pixels are indicated with 20ab, ac, bc, bd, and the junctions of the through trenches are indicated with N0, N2.

As shown in FIG. 11, the imaging device 1 according to the fourth embodiment is different from the imaging device 1 according to the second embodiment in that the FD portion 14a of the pixel 11a and the FD portion 14c of the pixel 11c are connected to the gate of the amplifying transistor 18b of the pixel 11b and the gate of an amplifying transistor 18d of the pixel 11d. Furthermore, the drain of the amplifying transistor 18b and the drain of the amplifying transistor 18d are electrically connected to each other. In other words, the amplifying transistor 18b and the amplifying transistor 18d are connected in parallel. Thus, an effective W length of the amplifying transistors can be increased, and the noise can be reduced, contributing to the improvement of the image quality.

Thus, the amplifying transistor 18b and the amplifying transistor 18d output the potentials of the FD portion 14a and the FD portion 14c which have been reset by the reset transistor 16d to the vertical signal line 121 as reset levels. Also, the potentials of the FD portion 14a and the FD portion 14c obtained after a signal charge is transferred by the transfer transistor 112 are output to the vertical signal line 121 as signal levels.

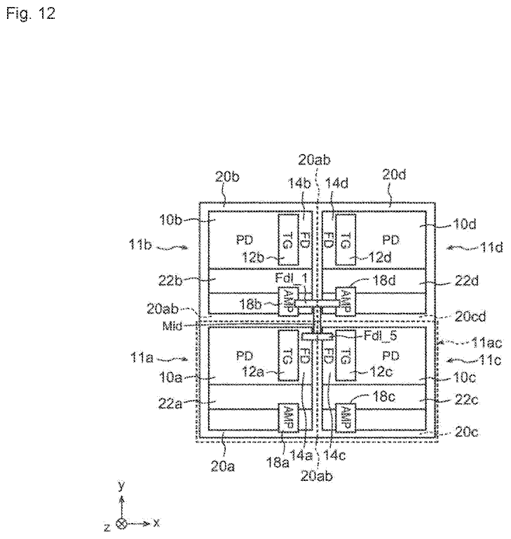

FIG. 12 is a diagram showing an example of a layout of the pixels 11a to 11d according to the fourth embodiment. FIG. 12 is a diagram in which the pixel array portion 120 (see FIG. 1) is viewed from the rear surface opposite to the light-receiving surface. As shown in FIG. 12, the imaging device 1 according to the fourth embodiment is different from the imaging device 1 according to the second embodiment in that the amplifying transistor 18d of the pixel 11d is arranged in the same layer as the transfer transistors (TG) 12a, 12c. Thus, the amplifying transistor 18b and the amplifying transistor 18d are arranged in the vicinity of the adjacent point Mid of the four pixels 11a, 11b, 11c, 11d adjacent to one another and are connected in parallel. Therefore, the effects of the imaging device 1 according to the second embodiment and the effective W length of the amplifying transistor 18b can be increased.

### Fifth Embodiment

An imaging device 1 according to a modification of a fifth embodiment is different from the imaging device 100 according to the first embodiment in that a pixel circuit AFD further includes a floating diffusion FD2 and that the capacitance of the floating diffusion can be changed. The differences with the imaging device 100 according to the first embodiment will be described below.

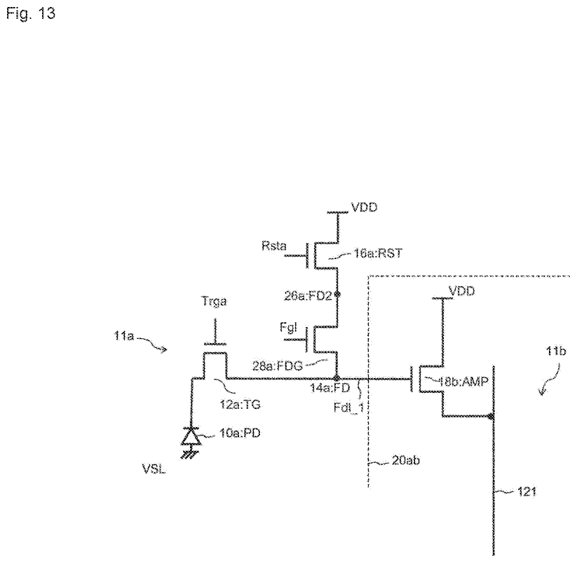

FIG. 13 is a circuit diagram showing an example of a circuit configuration of a pixel according to the fifth embodiment. FIG. 13 shows parts of the pixels 11a, 11b. Also, the through trench arranged between the pixels is indicated with 20ab.

As shown in FIG. 13, the pixel 11a further includes a second FD (floating diffusion) (FD2) portion 26a, a control line Fgl, and a transistor (FDG) 28a. A control signal is supplied to the control line Fgl and enters a connected state or disconnected state. The transistor 28a is, for example, an N-type MOS transistor.

One end of the reset transistor 16a (RST) is connected to the second FD portion 26a and the other end is connected to a power supply voltage VDD. Also, one end of the transistor 28a is connected to the FD portion 14a and the other end is connected to the second FD portion 26a. The gate of the transistor 28a is connected to the control line Fgl.

In this configuration, the transistor 28a can be brought into a conductive state, whereby the FD portion 14a and the second FD portion 26a are connected in parallel, increasing the capacitance. Thus, the case where the FD portion 14a is used and the case where the FD portion 14a and the second FD portion 26a are used can be switched in accordance with the imaging light intensity of the photoelectric conversion element 10a.

When using the FD portion 14a and the second FD portion 26a, the transistor 28a and the reset transistor 16a are brought into a conductive state on the basis of a control signal. Accordingly, charges stored in the FD portion 14a and the second FD portion 26a are discharged. Next, the reset transistor 16a is brought into a non-conductive state on the basis of a control signal. Accordingly, after the completion of an exposure period, the transfer transistor 12a enters a conductive state on the basis of a control signal, whereby the FD portion 14a and the second FD portion 26a store charges transferred from the photoelectric conversion element 10a via the transfer transistor 12a.

As described above, the amplifying transistor 18b of the pixel 11b has a source follower configuration in which the drain thereof is connected to a selective power supply SELVDD and the source to the vertical signal line 121, wherein the amplifying transistor 18b enters an operation state when the selective power supply SELVDD is at a VDD level, to select the pixel 11a. Consequently, the potentials of the FD portion 14a and the second FD portion 26a that have been reset by the reset transistor 16a are output to the vertical signal line 121 as reset levels. Further, the potentials of the FD portion 14a and the second FD portion 26a obtained after the transfer of a signal charge by the transfer transistor 112 are output to the vertical signal line 121.

When only the FD portion 14a is used, the transistor 28a (switching element FDG) and the reset transistor 16a (switching element RST) are brought into a conductive state on the basis of a control signal. Accordingly, charges stored in the FD portion 14a and the second FD portion 26a are discharged. Next, the transistor 28a enters a non-conductive state on the basis of a control signal. Thus, after the completion of an exposure period, the transfer transistor 12a (switching element TG) enters a conductive state on the basis of a control signal, whereby the FD portion 14a stores charges transferred from the photoelectric conversion element 10a via the transfer transistor 12a. Subsequently, the same processing as above is performed.

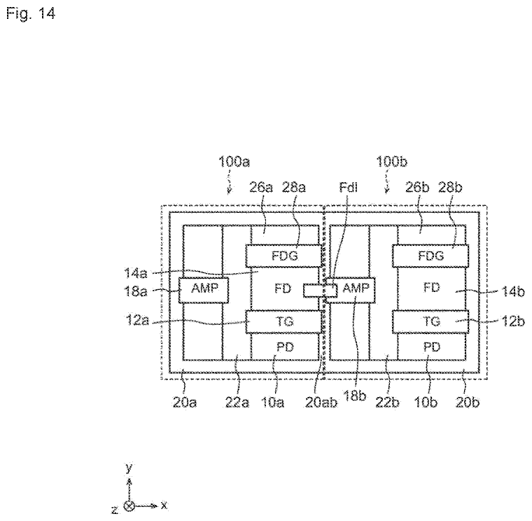

FIG. 14 is a diagram showing an example of a layout of the adjacent pixels 11a, 11b according to the fifth embodiment. FIG. 14 is a diagram in which the pixel array portion 120 (see FIG. 1) is viewed from the rear surface opposite to the light-receiving surface. As shown in FIG. 14, the pixel 11a is composed of a photoelectric conversion element (PD) 10a, an FD portion 14a which is a floating diffusion (FD), a second FD portion 26a which is a floating diffusion (FD2), and three pixel transistors, that is, a transfer transistor 12a, an amplifying transistor 18a, and a transistor 28a. The other pixel has the same configuration. A plurality of these pixels are arranged in a matrix in the pixel array portion 120. The reset transistor 16a is stacked on a circuit substrate layer having the transfer transistor 12a and the amplifying transistor 18a, the circuit substrate layer being not shown in the present embodiment. The reset transistor 16a (see FIG. 13) may also be arranged in the same layer as the transfer transistor 12a and the amplifying transistor 18a.

The pixel 11a is surrounded by the through trench 20a and the through trench 20ab which is the boundary between the pixel 11a and the pixel 11b, and is insulated from the adjacent pixel. Similarly, the pixel 11a is surrounded by a through trench 20b and the through trench 20ab which is the boundary between the pixel 11b and the pixel 11a, and is insulated from the adjacent pixel.

The FD portion 14a and the amplifying transistor 18b of the pixel 11b are connected by the conductive portion Fdl. In addition, the amplifying transistor 18a of the pixel 11a is separated from the FD portion 14a and the second FD portion 26a by the element separation region portion 22a.

As describe above, in the imaging device 100 according to the modification of the present embodiment, the pixel 11a further includes the second FD portion 26a. Thus, the effects of the imaging device 1 according to the first embodiment can be achieved, and the capacitance of the floating diffusion can be changed in accordance with the imaging light intensity of the photoelectric conversion element 10a.

### Sixth Embodiment

An imaging device 1 according to a sixth embodiment is different from the imaging device 100 according to the first embodiment in that the conductive portion Fdla extending across the through trench 20ab is configured by a shared contact. The differences with the imaging device 100 according to the first embodiment will be described below.

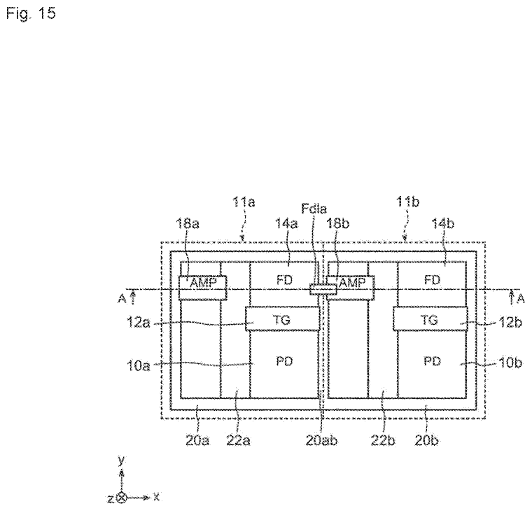

A conformation example of the pixel 11a and the pixel 11b according to the sixth embodiment are now described with reference to FIGS. 15 to 17. FIG. 15 is a diagram showing an example of a layout of the adjacent pixels 11a, 11b according to the sixth embodiment. That is, the imaging device 1 according to the sixth embodiment is different from the imaging device 100 according to the first embodiment in that, as shown in FIG. 15, the conductive portion Fdla extending across the through trench 20ab is configured by a shared contact.

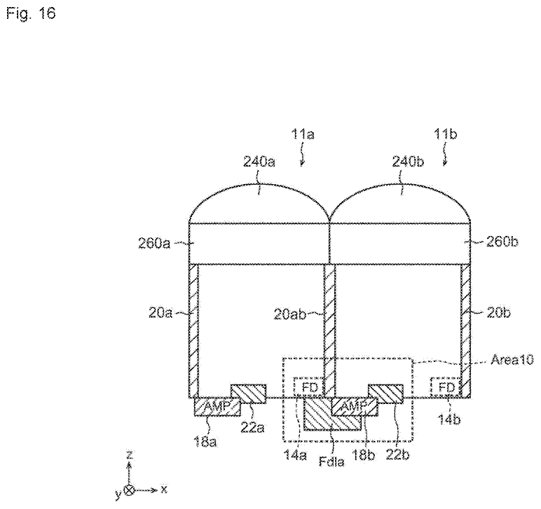

FIG. 16 is a cross-sectional view taken along AA of FIG. 15. As shown in FIG. 16, the FD portion 14a of the pixel 11a is configured to be closer to the through trench 20ab. More specifically, the FD portion 14a of the pixel 11a is configured to be adjacent to the through trench 20ab.

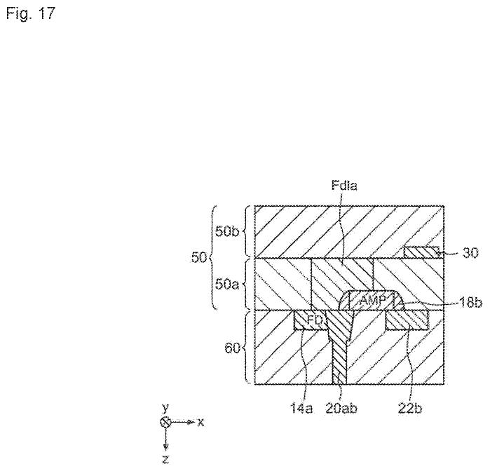

FIG. 17 is a diagram showing an enlargement of an Area 10 of FIG. 16. At least parts of the photoelectric conversion element 10a of the pixel 11a (see FIG. 2), the element separation region portion 22b, and the through trench 20ab are configured within a semiconductor layer 60. Also, an insulation layer 50 in contact with the semiconductor layer 60 includes a first insulation layer 50a and a wiring phase 50b. In the insulation layer 50, at least parts of the conductive portion Fdla and the amplifying element 18b are configured. More specifically, the conductive portion Fdla is configured inside the first insulation layer 50 by a shared contact. The shared contact is constituted by tungsten, for example.

As shown in FIG. 17, the FD portion 14a of the pixel 11a and the amplifying element 18b of the pixel 11b are configured to be closer to the through trench 20ab. Also, the conductive portion Fdla is configured to extend across the through trench 20ab so as to cover the surfaces of the FD portion 14a and the amplifying element 18b. As can be understood from this, the length of the conductive portion Fdla can be configured to be shorter to electrically connect the FD portion 14a and the amplifying element 18b. Thus, the conversion efficiency η of the imaging device 1 shown in the equation (1) can be made greater than the conversion efficiency η of the first embodiment.

As described above, according to the present embodiment, the FD portion 14a of the pixel 11a and the amplifying element 18b of the pixel 11b are configured to be closer to the through trench 20ab, and the conductive portion Fdla is configured by the shared contact so as to cover the FD portion 14a and the amplifying element 18b. Thus, the length of the conductive portion Fdla can be made shorter, and the conversion efficiency η of the imaging device 1 can be increased.

### Seventh Embodiment

An imaging device 1 according to a seventh embodiment is different from the imaging device 100 according to the first embodiment in that the conductive portion Fdlb extending across the through trench 20ab is configured by a polycontact. The differences with the imaging device 100 according to the first embodiment will be described below.

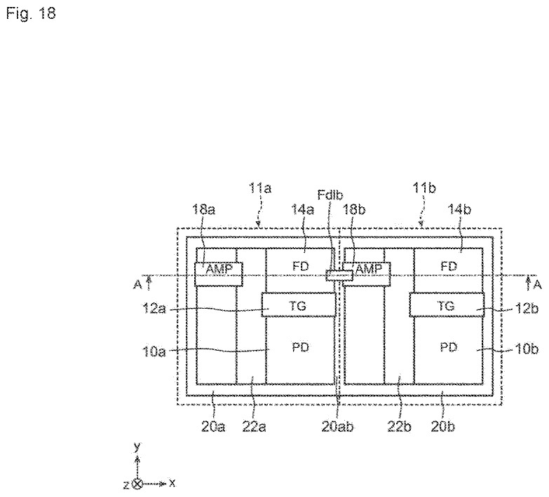

A conformation example of the pixel 11a and the pixel 11b according to the seventh embodiment are now described with reference to FIGS. 18 to 20. FIG. 18 is a diagram showing an example of a layout of the adjacent pixels 11a, 11b according to the seventh embodiment. That is, the imaging device 1 according to the seventh embodiment is different from the imaging device 100 according to the first embodiment in that, as shown in FIG. 18, the conductive portion Fdlb extending across the through trench 20ab is configured by a polycontact.

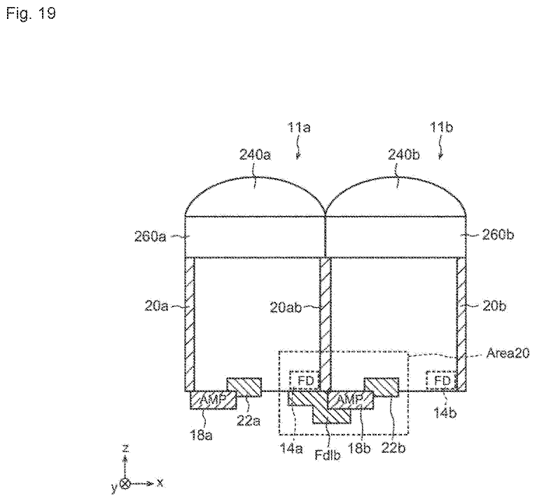

FIG. 19 is a cross-sectional view taken along AA of FIG. 18. As shown in FIG. 19, the FD portion 14a of the pixel 11a is configured to be closer to the through trench 20ab. More specifically, the FD portion 14a of the pixel 11a is configured to be adjacent to the through trench 20ab.

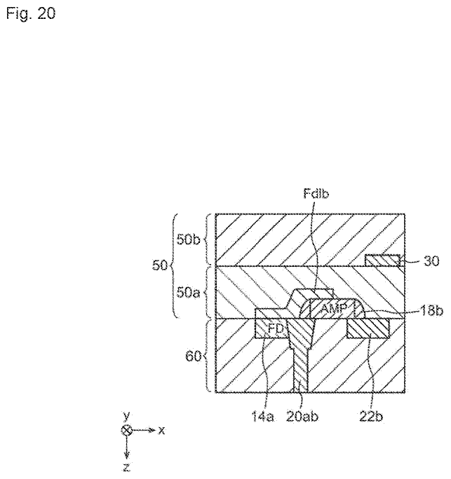

FIG. 20 is a diagram showing an enlargement of an Area 20 of FIG. 19. At least parts of the photoelectric conversion element 10a of the pixel 11a (see FIG. 2), the element separation region portion 22b, and the through trench 20ab are configured within the semiconductor layer 60. Also, the insulation layer 50 in contact with the semiconductor layer 60 includes the first insulation layer 50a and the wiring phase 50b. In the insulation layer 50, at least parts of the conductive portion Fdlb and the amplifying element 18b are configured. More specifically, the conductive portion Fdlb is configured inside the first insulation layer 50 by a polycontact. The polycontact is constituted by polysilicon, for example.

As shown in FIG. 20, the FD portion 14a of the pixel 11a and the amplifying element 18b of the pixel 11b are configured to be closer to the through trench 20ab. Also, the conductive portion Fdla is configured to extend across the through trench 20ab so as to cover the surfaces of the FD portion 14a and the amplifying element 18b. As can be understood from this, the length of the conductive portion Fdlb can be configured to be shorter to electrically connect the FD portion 14a and the amplifying element 18b. Thus, the conversion efficiency η of the imaging device 1 shown in the equation (1) can be made greater than the conversion efficiency η of the first embodiment.

As described above, according to the present embodiment, the FD portion 14a of the pixel 11a and the amplifying element 18b of the pixel 11b are configured to be closer to the through trench 20ab, and the conductive portion Fdlb is configured by the polycontact so as to cover the FD portion 14a and the amplifying element 18b. Thus, the length of the conductive portion Fdlb can be made shorter, and the conversion efficiency η of the imaging device 1 can be increased.

### Eighth Embodiment

An imaging device 1 according to an eighth embodiment is different from the imaging device 100 according to the first embodiment in that the conductive portion Fdlc extending across the through trench 20ab is configured inside the first insulation layer 50a. The differences with the imaging device 100 according to the first embodiment will be described below.

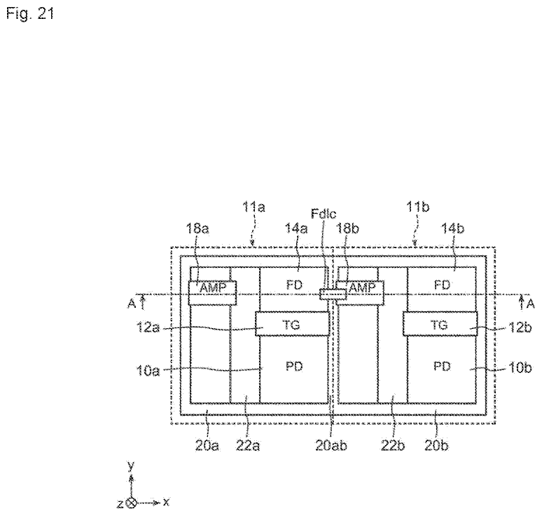

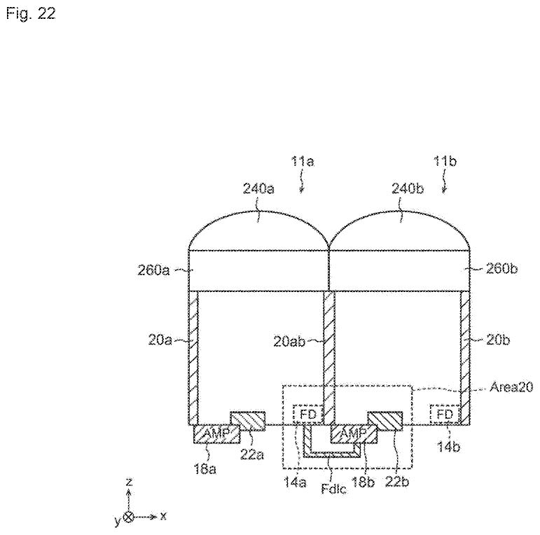

A conformation example of the pixel 11a and the pixel 11b according to the eighth embodiment are now described with reference to FIGS. 21 to 23. FIG. 21 is a diagram showing an example of a layout of the adjacent pixels 11a, 11b according to the seventh embodiment. FIG. 22 is a cross-sectional view taken along AA of FIG. 21. The imaging device 1 according to the eighth embodiment is different from the imaging device 100 according to the first embodiment in that, as shown in FIG. 22, the conductive portion Fdlc extending across the through trench 20ab is configured to be closer to the FD portion 14a and the amplifying element 18b.

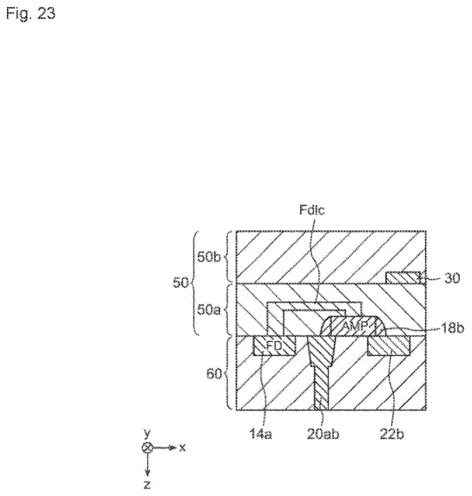

FIG. 23 is a diagram showing an enlargement of an Area 30 of FIG. 22. At least parts of the photoelectric conversion element 10a of the pixel 11a (see FIG. 2), the element separation region portion 22b, and the through trench 20ab are configured within the semiconductor layer 60. Also, the insulation layer 50 in contact with the semiconductor layer 60 includes the first insulation layer 50a and the wiring phase 50b. In the insulation layer 50, at least parts of the conductive portion Fdlc and the amplifying element 18b are configured. More specifically, the conductive portion Fdlc is configured inside the first insulation layer 50a by a polycontact. The conductive portion Fdlc is constituted by metal wiring, for example.

As shown in FIG. 23, the conductive portion Fdlc is configured to extend across the through trench 20ab within the first insulation layer 50a. As can be understood from this, the length of the conductive portion Fdlc can be configured to be shorter to electrically connect the FD portion 14a and the amplifying element 18b. Thus, the conversion efficiency η of the imaging device 1 shown in the equation (1) can be made greater than the conversion efficiency η of the first embodiment.

As described above, according to the present embodiment, the conductive portion Fdlc that connects the FD portion 14a and the amplifying element 18b is configured within the insulation layer 50a positioned closer to the FD portion 14a and the amplifying element 18b than the wiring layer 50b. Thus, the length of the conductive portion Fdlc can be made shorter, and the conversion efficiency η of the imaging device 1 can be increased.

### Ninth Embodiment

An imaging device 1 according to a ninth embodiment is different from the imaging device 100 according to the first embodiment in that imaging is possible by means of global shuttering. The differences with the imaging device 100 according to the first embodiment will be described below.

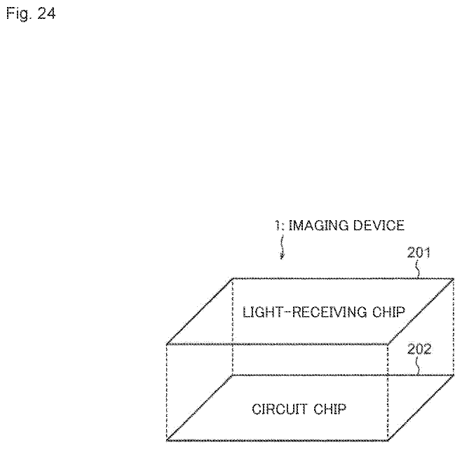

A conformation example of the pixel 11a according to the ninth embodiment and a conformation example of parts of the pixel 11b and the pixel 11c are now described with reference to FIGS. 24 to 27. FIG. 24 is a diagram showing an example of a laminated structure of the imaging device 1 according to the present embodiment. This imaging device 1 includes a circuit chip 202 and a light-receiving chip 201 stacked on the circuit chip 202. These chips are connected by a Cu—Cu junction, a via, or a bump.

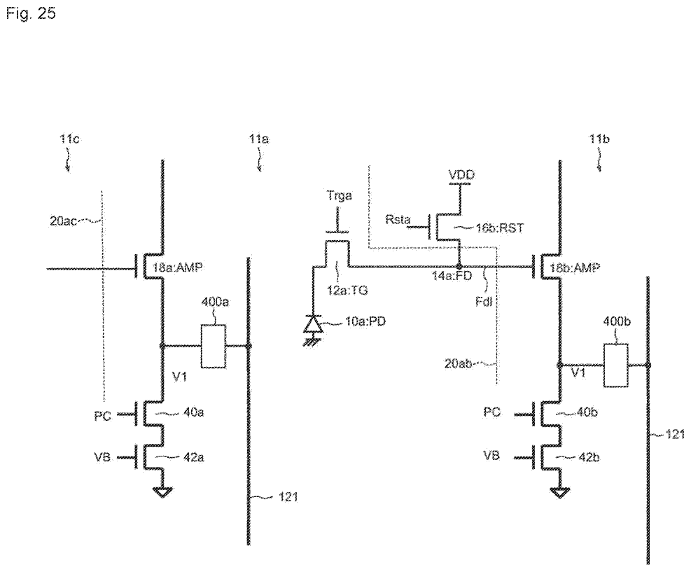

FIG. 25 is a circuit diagram showing an example of a circuit configuration of a pixel according to the ninth embodiment. FIG. 25 shows parts of the pixels 11a, 11b. Also, the through trench arranged between the pixels is indicated with 20ab. As shown in FIG. 25, the pixels 11a, 11b according to the ninth embodiment includes a connection transistor 40, a load MOS transistor 42, and sample-and-hold circuits 400a, b. An image signal of the pixel 11a is sample-held by the sample-and-hold circuit 400b of the pixel 11b. Similarly, an image signal of the pixel 11c is sample-held by the sample-and-hold circuit 400a of the pixel 11a.

The connection transistor 40 opens/closes a path between the load MOS transistor 42 and an input node 350 in accordance with a control signal PC from the vertical selection circuit 130. A predetermined bias voltage VB is applied to the gate of the load MOS transistor 42. A load current corresponding to the bias voltage is supplied to the load MOS transistor 42. These connection transistor 40, load MOS transistor 42, and sample-and-hold circuits 400a, b are configured in, for example, the circuit chip 202 (see FIG. 24).

In this manner, in the imaging device 1 according to the ninth embodiment, the sample-and-hold circuit 400 corresponding to each pixel 11 is configured. Therefore, data related to exposures of the respective pixels 11 can be sample-held simultaneously by the sample-and-hold circuit 400, enabling imaging by means of global shuttering where the respective pixels 11 are exposed simultaneously.

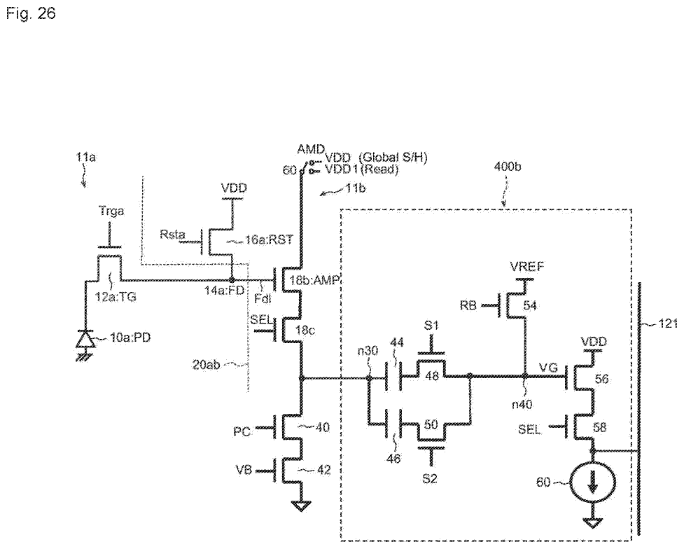

FIG. 26 is a circuit diagram showing an example of a detailed circuit configuration of the sample-and-hold circuit 400b of the pixel 11b. Note that the sample-and-hold circuit 400b is not limited to have the configuration shown in FIG. 26; a general circuit can be used.

The sample-and-hold circuit 400b includes individual capacitances 44 and 46, transistors 48, 50, a connection transistor 54, an amplifying transistor 56, a selection transistor 58, and a current source 60. Examples of the transistors used in the sample-and-hold circuit 400b include an nMOS transistor. The sample-and-hold circuit 400a has the same configuration as the sample-and-hold circuit 400b.

Examples of the individual capacitance 44 and the individual capacitance 46 used include a MIM element. Capacitance values of these capacitances are identical. Further, ends on one side of these individual capacitance 44 and individual capacitance 46 (the right-hand side in the diagram) are connected to an output-side node n40 via the transistors 48, 50. The voltage of this output-side node n40 is denoted as VG. In addition, the ends on the other side of the individual capacitance 44 and the individual capacitance 46 are connected to an input node n30.

The transistor 48 opens/closes a path between the other end of the individual capacitance 44 (the left-hand side in the diagram) and the output-side node n40 in accordance with a control signal S1 from the vertical selection circuit 130. The transistor 50 opens/closes a path between the other end of the individual capacitance 46 (the left-hand side in the diagram) and the output-side node n40 in accordance with a control signal S2 from the vertical selection circuit 130. The connection transistor 54 opens/closes a path between a node of a reference voltage VREF and the output-side node n40 in accordance with a control signal RB from the vertical selection circuit 130.

The amplifying transistor 56 amplifies the voltage VG of the output-side node n40. The selection transistor 58 outputs a signal of the voltage obtained after amplification by the amplifying transistor 56, to the vertical signal line 121, in accordance with a control signal SEL from the vertical selection circuit 130. The signal of the vertical signal line 121 is supplied to the column circuit 140 (see FIG. 1) as an analog output signal Aout.

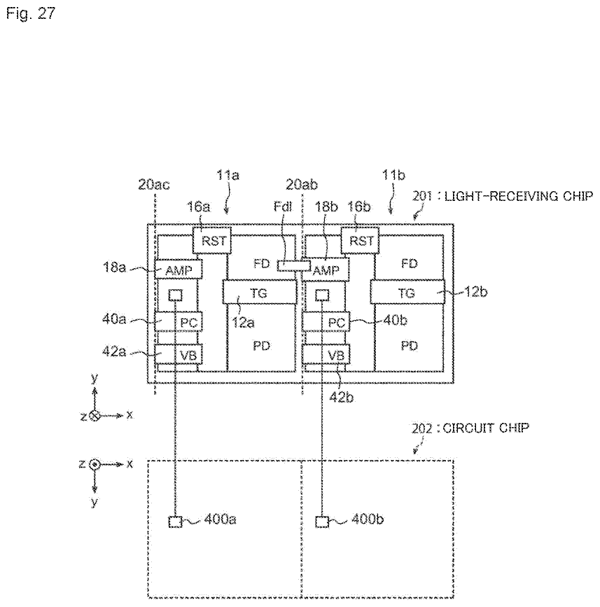

FIG. 27 is a diagram showing an example of a layout of the adjacent pixels 11a, 11b according to the ninth embodiment. FIG. 27 corresponds to the circuit diagrams of FIGS. 25 and 26.

### Operation Examples

Over the pulse period from the timing immediately before the end of the exposure period, the vertical selection circuit 130 sets the level of a reset signal Rsta to a high level. Furthermore, a changeover switch 62 is switched to a power supply VDD node. As a result, the FD portion 14a of the pixel 11a is initialized. The level of the pixel signal at this initialization is referred to as a reset level.

Next, the vertical selection circuit 130 sets the levels of the control signals RB, SEL, and S1 to a high level. During this period, the reset level of the pixel 11a is sample-held.

Next, the vertical selection circuit 130 sets the level of the control signal S1 to a low level, and sets the levels of the control signal S2 and a transfer signal TRG to a high level. As a result, the load corresponding to the exposure amount is transferred to the FD portion 14a. The level of the pixel signal at this time of transfer is referred to as a signal level. In addition, during this period, the signal level of the pixel 11a is sample-held. The vertical selection circuit 130 sets the levels of the control signals S1, S2, RB to a low level.

The vertical selection circuit 130 then sets the level of the reset signal Rsta to a high level and the level of the control signal PC to a low level. Such control is performed for all pixels simultaneously. That is, exposure is performed by means of global shuttering. By this global shuttering, the timings for starting and ending the exposures of all pixels can be matched.

Next, at the timing for starting a reading period, the changeover switch 62 is switched to a (READ) node. The vertical selection circuit 130 sets the level of the control signal S1 to a high level and the level of the control signal SEL to a high level. The voltage VG becomes a potential corresponding to the reset level, and an ADC of the column circuit 140 performs AD conversion (readout) corresponding to the level by down-counting. The vertical selection circuit 130 then sets the level of the control signal S2 to a low level and the levels of the control signals S1, SEL to a high level. The voltage VG becomes a potential corresponding to the signal level, and the ADC of the column circuit 140 performs AD conversion (readout) corresponding to the level by up-counting. Since the reset level is subjected to AD conversion by down-counting, the reset level becomes eliminated as an offset value by up-counting performed thereafter. As a result, the potential corresponding to the signal level is read out by the column circuit 140.

As described above, in the imaging device 1 according to the present embodiment, the sample-and-hold circuit 400 corresponding to each pixel 11 is configured. Therefore, data related to exposures of the respective pixels 11 can be sample-held simultaneously by the sample-and-hold circuit 400, enabling imaging by means of global shuttering where the respective pixels 11 are exposed simultaneously.

The present technique can also take on the following configurations.

(1)

An imaging device composed of a plurality of pixels, wherein
a first pixel among the plurality of pixels includes:
a first photoelectric conversion element;
a first power storage unit;
a first transfer element that enables a conductive state or a non-conductive state between the first photoelectric conversion element and the first power storage unit; and
a first amplifying element that amplifies an image signal on the basis of a charge stored by photoelectric conversion in at least any of adjacent pixels, including a second pixel, that are adjacent to the first pixel,
the second pixel including:
a second amplifying element that amplifies an image signal based on a charge stored in the first power storage unit by photoelectric conversion of the first photoelectric conversion element, and
a second distance between the first power storage unit and the second amplifying element is shorter than a first distance between the first power storage unit and the first amplifying element.
   (2)

The imaging device according to (1), further comprising:
a through trench arranged between the first pixel and the adjacent pixels; and
a first element separation region portion that isolates and separates the first amplifying element and the first power storage unit by an insulating substance, wherein
a width between the first amplifying element and the first power storage unit in the first element separation region portion is greater than a width of the through trench.
   (3)

The imaging device according to (2), wherein the first power storage unit and the second amplifying element are connected by a conductive portion extending across the through trench.

(4)

The imaging device according to (3), further comprising:
a semiconductor layer; and
an insulation layer,
wherein
the semiconductor layer includes at least parts of the first photoelectric conversion element, the first element separation region portion, and the through trench,
the insulation layer includes at least the conductive portion out of the conductive portion and the second amplifying element, and
the conductive portion is any of metal wiring, a shared contact, and a polycontact.
   (5)

The imaging device according to (4), wherein the insulation layer includes a first insulation layer and a wiring layer, and
a region of the metal wiring extending across the through trench is arranged in the first insulation layer or the wiring layer.
   (6)

The imaging device according to (5), wherein the insulation layer is arranged on a rear surface side opposite to a side where imaging light enters the first photoelectric conversion element.

(7)

The imaging device according to (6), wherein the through trench is a rear surface through trench etched from the rear surface side.

(8)

The imaging device according to (6), wherein the through trench is a front surface through trench etched from the side where the imaging light enters.

(9)

The imaging device according to (8), wherein a third pixel that is different from the first pixel and the second pixel among the plurality of pixels and is adjacent to the first pixel includes:
a third photoelectric conversion element; and
a third power storage unit,
the first pixel further including a first amplifying element that amplifies an image signal based on a charge stored in the third power storage unit by photoelectric conversion of the third photoelectric conversion element.
   (10)

The imaging device according to (9), wherein the first element separation region portion has an oxide film-embedded structure.

(11)

The imaging device according to (9), wherein the first element separation region portion has an implantation separation structure obtained by ion implantation.

(12)

The imaging device according to (1), wherein the plurality of pixels have an oxide film-embedded structure and an implantation separation structure as an element separation region portion.

(13)

The imaging device according to (4), wherein a connector between the metal wiring and the first power storage unit has a contact structure.

(14)

The imaging device according to (13), wherein the contact structure is a metal structure.

(15)

The imaging device according to (13), wherein the contact structure is a polysilicon structure.

(16)

The imaging device according to (1), wherein a fourth pixel that is different from the first pixel and the second pixel among the plurality of pixels and is adjacent to the first pixel includes:
a fourth photoelectric conversion element; and
a fourth power storage unit,
the fourth power storage unit being connected to the first power storage unit.
   (17)

The imaging device according to (1), wherein a fifth pixel that is different from the first pixel and the second pixel among the plurality of pixels and is adjacent to the second pixel includes:
a fifth amplifying element that amplifies an image signal based on a charge stored in the first power storage unit by photoelectric conversion of the first photoelectric conversion element.
   (18)

The imaging device according to (17), wherein the second amplifying element and the fifth amplifying element are connected in parallel.

(19)

The imaging device according to (16), wherein a fifth pixel that is different from the first pixel, the second pixel, and the fourth pixel among the plurality of pixels and is adjacent to the second pixel includes:
a reset element that has one end connected to the fourth power storage unit and the first power storage unit.
   (20)

The imaging device according to (1), wherein the first pixel further includes: a second power storage unit that stores an accumulated charge obtained by the first photoelectric conversion element;
an element that has one end connected to the first power storage unit and the other end connected to the second power storage unit; and
a reset element that has one end connected to the element.

Aspects of the present disclosure are not limited to the aforementioned individual embodiments and include various modifications that those skilled in the art can achieve, and effects of the present disclosure are also not limited to the details described above. In other words, various additions, modifications, and partial deletion can be made without departing from the conceptual idea and the gist of the present disclosure that can be derived from the details defined in the claims and the equivalents thereof.

1. An imaging device composed of a plurality of pixels, wherein
a first pixel among the plurality of pixels includes:
a first photoelectric conversion element;
a first power storage unit;
a first transfer element that enables a conductive state or a non-conductive state between the first photoelectric conversion element and the first power storage unit; and
a first amplifying element that amplifies an image signal on the basis of a charge stored by photoelectric conversion in at least any of adjacent pixels, including a second pixel, that are adjacent to the first pixel,
the second pixel including:
a second amplifying element that amplifies an image signal based on a charge stored in the first power storage unit by photoelectric conversion of the first photoelectric conversion element, and
a second distance between the first power storage unit and the second amplifying element is shorter than a first distance between the first power storage unit and the first amplifying element.

2. The imaging device according to claim 1, further comprising:
a through trench arranged between the first pixel and the adjacent pixels; and
a first element separation region portion that isolates and separates the first amplifying element and the first power storage unit by an insulating substance, wherein
a width between the first amplifying element and the first power storage unit in the first element separation region portion is greater than a width of the through trench.

3. The imaging device according to claim 2, wherein the first power storage unit and the second amplifying element are connected by a conductive portion extending across the through trench.

4. The imaging device according to claim 3, further comprising:
a semiconductor layer; and
an insulation layer,
wherein
the semiconductor layer includes at least parts of the first photoelectric conversion element, the first element separation region portion, and the through trench,
the insulation layer includes at least the conductive portion out of the conductive portion and the second amplifying element, and
the conductive portion is any of metal wiring, a shared contact, and a polycontact.

5. The imaging device according to claim 4, wherein the insulation layer includes a first insulation layer and a wiring layer, and
a region of the metal wiring extending across the through trench is arranged in the first insulation layer or the wiring layer.

6. The imaging device according to claim 5, wherein the insulation layer is arranged on a rear surface side opposite to a side where imaging light enters the first photoelectric conversion element.

7. The imaging device according to claim 6, wherein the through trench is a rear surface through trench etched from the rear surface side.

8. The imaging device according to claim 6, wherein the through trench is a front surface through trench etched from the side where the imaging light enters.

9. The imaging device according to claim 8, wherein a third pixel that is different from the first pixel and the second pixel among the plurality of pixels and is adjacent to the first pixel includes:
a third photoelectric conversion element; and
a third power storage unit,
the first pixel further including a first amplifying element that amplifies an image signal based on a charge stored in the third power storage unit by photoelectric conversion of the third photoelectric conversion element.

10. The imaging device according to claim 9, wherein the first element separation region portion has an oxide film-embedded structure.

11. The imaging device according to claim 9, wherein the first element separation region portion has an implantation separation structure obtained by ion implantation.

12. The imaging device according to claim 1, wherein the plurality of pixels have an oxide film-embedded structure and an implantation separation structure as an element separation region portion.

13. The imaging device according to claim 4, wherein a connector between the metal wiring and the first power storage unit has a contact structure.

14. The imaging device according to claim 13, wherein the contact structure is a metal structure.

15. The imaging device according to claim 13, wherein the contact structure is a polysilicon structure.

16. The imaging device according to claim 1, wherein a fourth pixel that is different from the first pixel and the second pixel among the plurality of pixels and is adjacent to the first pixel includes:
a fourth photoelectric conversion element; and
a fourth power storage unit,
the fourth power storage unit being connected to the first power storage unit.

17. The imaging device according to claim 1, wherein a fifth pixel that is different from the first pixel and the second pixel among the plurality of pixels and is adjacent to the second pixel includes:
a fifth amplifying element that amplifies an image signal based on a charge stored in the first power storage unit by photoelectric conversion of the first photoelectric conversion element.

18. The imaging device according to claim 17, wherein the second amplifying element and the fifth amplifying element are connected in parallel.

19. The imaging device according to claim 16, wherein a fifth pixel that is different from the first pixel, the second pixel, and the fourth pixel among the plurality of pixels and is adjacent to the second pixel includes:
a reset element that has one end connected to the fourth power storage unit and the first power storage unit.

20. The imaging device according to claim 1, wherein the first pixel further includes:
a second power storage unit that stores an accumulated charge obtained by the first photoelectric conversion element;
an element that has one end connected to the first power storage unit and the other end connected to the second power storage unit; and
a reset element that has one end connected to the element.
